(19) United States
(12) Patent Application Publication
(10) Pub. No.: US 2016/0142045 A1
(43) Pub. Date: May 19, 2016

(54) ASYNCHRONOUS CLOCK ENABLEMENT

(71) Applicant: GainSpan Corporation, San Jose, CA (US)

(72) Inventor: Robert MACK, San Jose, CA (US)

(21) Appl. No.: 14/543,205

(22) Filed: Nov. 17, 2014

(51) Int. Cl. H03K 5/01

(52) U.S. Cl. CPC H03K 5/01

(57) ABSTRACT

An asynchronous clock enable system includes a clock generation device configured to generate a first clock signal to operate a target resource. The asynchronous clock enable system also includes a clock gating device coupled to the clock generation device to determine when the first clock signal achieves stability. The clock gating device generates a clock gating signal to enable the first clock signal when the first clock signal achieves stability. The clock gating device is asynchronous relative to the clock request signal.

### BACKGROUND

1. Field

Aspects of the present disclosure relate to oscillators, and more particularly to methods and systems for mitigating system instability of a clock generator that is controlled by a clock signal of a clock where the clock signal may be unstable.

2. Background

Most integrated circuits (ICs) of sufficient complexity use a clock signal in order to synchronize different parts of the circuit. In some cases, more than one clock cycle is required to perform a predictable action. As ICs become more complex, the problem of supplying accurate and synchronized clocks to all the circuits becomes increasingly difficult.

In many ICs, the clock signal is controlled by a circuit or control block that is outside of the clock signal's “domain,”, i.e., the clock is controlled by an outside reference signal or clock control signal from an outside source.

The clock signal for digital circuitry produces a glitchless, stable signal that is used to organize the operation of the overall digital circuit. If the clock signal has glitches, i.e., is unstable in amplitude, frequency, or has spikes within the waveform, the digital circuit may not respond properly or in an organized fashion. For example, and not by way of limitation, a crystal oscillator circuit operates by taking a signal from a crystal, amplifying that signal and feeding the signal back to the crystal to sustain or increase the crystal's oscillation. When power is initially applied to a crystal oscillator circuit, the crystal begins to warm-up over a period of time where the crystal operates at less than normal operating frequency and error range. The oscillations grow over time and finally they reach a stable or steady state value or amplitude and a steady state frequency. In some applications, the amount of time required to power up and stabilize an oscillator may be longer than desirable. Other glitches in such a system may be, for example, that the clock signal is “gated” at the wrong time and appears to be a shortened clock pulse to the remainder of the circuitry. Accordingly, for these applications it is desirable to reduce the time required to power up and stabilize the oscillator.

### SUMMARY

According to one aspect of the present disclosure, an asynchronous clock enable system includes a clock control block. The clock control block includes a clock generation device and a clock gating device coupled to the clock generation device, The clock control block operates within a domain of the clock control block.

According to one aspect of the present disclosure, an asynchronous clock enable method includes controlling a domain of a clock with a clock control block. The method also includes generating, by a clock generation device, a clock signal to operate a target resource. The method also includes determining, by a clock gating device coupled to the clock generation device, when the clock signal achieves stability. The method further includes generating, by the clock gating device, a clock gating signal to enable the clock signal when the clock signal achieves stability. The clock gating device is asynchronous with the first clock signal and the clock control block operates within a domain of the clock control block.

According to one aspect of the present disclosure, an asynchronous clock enable system includes means for generating a first clock signal to operate a target resource. The asynchronous clock enable system also includes means for determining when the first clock signal achieves stability. The asynchronous clock enable system further includes means for generating a clock gating signal to enable the first clock signal when the first clock signal achieves stability. The determining means being asynchronous relative to the first clock signal.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an exemplary clock control block for generating gated clock signals according to one or more aspects of the present disclosure.

FIG. 2 illustrates exemplary timing diagram of various timing signals of the asynchronous clock enable system of FIG. 1 according to one or more aspects of the present disclosure.

FIG. 3 illustrates exemplary timing diagram of various timing signals of the asynchronous clock enable system of FIG. 1 according to one or more aspects of the present disclosure.

FIG. 4 illustrates exemplary timing diagram of various timing signals of the asynchronous clock enable system of FIG. 1 for a single clock glitch according to one or more aspects of the present disclosure.

FIG. 5 illustrates exemplary timing diagram of various timing signals of the asynchronous clock enable system of FIG. 1 for a double clock glitch according to one or more aspects of the present disclosure.

FIG. 6 illustrates exemplary timing diagram of various timing signals of the asynchronous clock enable system of FIG. 1 for a triple clock glitch according to one or more aspects of the present disclosure.

FIG. 7 illustrates an asynchronous clock enable method in accordance with one or more aspects of the disclosure.

FIG. 8 is a diagram illustrating an example of a hardware implementation for an apparatus employing an asynchronous clock enable system.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

### Overview

Aspects of the present disclosure relate to methods and systems for mitigating frequency instability of a clock generator that is controlled by a clock domain where the clock signal may be unstable. Because the stability of the clock generator is important to applications or target resources, aspects of the present disclosure seek to determine or predict when an actual stable operation of the clock domain is initiated. For example, the methods and systems may be implemented in accordance with an asynchronous clock gating system. The asynchronous clock gating system may include the clock generator coupled to a state machine. The clock generator may generate a clock domain and the state machine may generate a state machine internal clock. The clock domain may be asynchronous relative to the state machine internal clock. The clock domain may be implemented in accordance with a phase locked loop. For example, the clock domain may include a crystal oscillator that generates oscillatory clock signals that may be locked in frequency and phase to a reference signal. In some aspects, the clock generator may be coupled to a frequency stabilization counter via the state machine. The frequency stabilization may count the clock pulses generated by the clock domain to determine when the clock domain achieves an actual stable state or operation.

The actual stable operation/state of the clock domain may be concurrent with an active state of the state machine internal clock. The stable state of the state machine internal clock may be indicated by an internal clock indication signal (e.g., Cₛₛ) The signal Cₛₛ may be generated when the state machine internal clock is active. In some aspects of the disclosure, the actual stable state of the clock domain may be based on a frequency stabilization counter that indicates when the clock domain achieves actual stable state. The indication from the frequency stabilization counter may be based on previous clock pulse counts that previously indicated the stable state of the master under similar conditions. In some aspects, the clock domain signal is passed on to the target source when the clock domain achieves actual stable state and when the state machine internal clock is active.

In one aspect of the present disclosure, the clock state machine may run on its own domain, independent of the clock generator. The domain of the state machine operates such that the state machine is asynchronously coupled to the clock generator. The state machine in conjunction with the frequency stabilization counter may function as a clock gating device for activating/deactivating different clock resources to facilitate the provision of a clock domain signal to a target resource. For example, the clock gating device passes the clock signal of the clock domain to the target resource when the state machine internal clock achieves an active state and the clock domain achieves actual stability. Conversely, the clock gating device inhibits or blocks the clock signal from reaching the target resource when the state machine internal clock is inactive (i.e., when the state machine internal clock is in a sleep mode or settled mode).

The actual stable operation of the clock domain may be indicated before the clock domain settles into a final amplitude, for example. As noted, the actual stable state of the clock domain may correspond to the active state of a state machine internal clock. Although the clock generator may indicate that the clock domain has achieved an initial stable state, the clock signal of the clock domain may only be enabled after the state machine internal clock is active. In other words, the output clock signal of the clock domain may only be enabled when an actual stable operation of the clock domain is initiated.

When the clock domain signal is passed on to the target resource, the target resource responds to commands relative to one or more edges of the clock domain signal. When state machine is inactive, the target resource behaves as if the clock domain signal has stopped. Thus, clock signal from the clock domain may be enabled or disabled based on a clock gating signal, which depends on the operation of the state machine internal clock, rather than the operation of the clock domain. Thus, the clock signal of the clock domain may be disabled even though the clock generator indicates that the clock domain has achieved an initial stable state.

In one aspect of the disclosure, the state machine disables the clock signal from the clock domain by gating the clock signal to a logic low. The state machine may disable the clock signal based on the clock pulse count determined by the frequency stabilization counter. The clock pulse count may indicate whether the clock domain of the clock generation block has achieved actual stability based on a stabilization history of the clock domain. For example, the clock signal from the clock domain may achieve actual stability when the pulse count of the clock domain signal corresponds to a previously determined clock pulse count that indicated a start of a stable clock domain. For example, if the clock domain for a previous operation related to a target resource achieved actual stability after fifty nine pulse counts, the state machine may enable the current clock domain signal after fifty nine pulse counts. In some aspects, a target clock pulse count may be determined based on other parameters.

### Asynchronous Clock Enable System

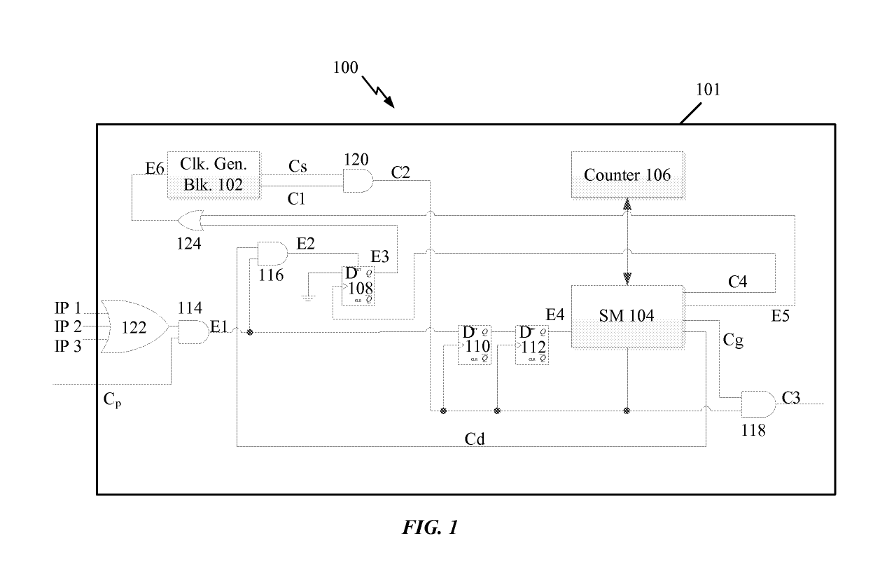

FIG. 1 illustrates an exemplary asynchronous clock control block 100 according to one or more aspects of the present disclosure.

The asynchronous clock enable block 100 includes a clock generation block 102 (e.g., clock generator), a state machine 104, a frequency stabilization counter 106 and other logic circuits. The clock generation block 102 generates a clock domain 101 used for the clock enable block 100 and the target clock domain through output C3. As noted, the state machine 104 is asynchronously coupled to the clock generation block 102. For example, the state machine 104 includes a state machine internal clock E4 that uses the clock domain generated by the clock generation block 102. The state machine 104 enables a clock domain signal C1 that is provided to the target resource(s) within an integrated circuit system. The clock domain signal C1 may be enabled when the pulse count of the clock domain signal C1 meets a desirable pulse count. The desirable pulse count may indicate whether the clock domain of the clock generation block has achieved actual stability based on the stabilization, specification, and/or history of the clock domain. The target resources may be in a target domain, which is a subset of the clock domain 101 that is stable and glitchless.

The clock domain may have different types of instability, or glitches, that appear in the clock signal. One type of instability is when the clock domain is first powered, where the first several clock pulses do not have a consistent shape or amplitude. Once an entire clock pulse has a stable pulse shape and amplitude, the frequency of the clock pulse then becomes stable. Another type of instability for clock domain signals is when the clock signal is enabled at the wrong time, because then the clock signal looks like a shortened pulse. Such signals may depend on the gating of the clock domain or how the clock domain is enabled. Enabling a clock domain, or making a clock request, may be asynchronously performed, while disabling a clock domain or gating the clock domain may be synchronously performed, to avoid these instabilities.

The frequency stabilization counter 106 may be coupled to the clock generation block 102 via the state machine 104. The frequency stabilization counter 106 counts the pulses of the clock domain through clock domain signals received by the state machine 104. In one aspect of the disclosure, the state machine 104 may be a controller or processor and the frequency stabilization counter may be incorporated into the state machine 104. In other aspects, the actual stability of the clock domain may be determined based on other implementations instead of the pulse count. The frequency stabilization counter 106 may provide an indication of the pulse count of the clock domain to the state machine 104. The state machine 104 may determine when to enable clock domain signal C1 based on the pulse count. For example, the state machine 104 may enable the clock domain signal C1 when the pulse count from the frequency stabilization counter 106 is equivalent or greater than a desirable pulse count. The desirable pulse count may match a previous pulse count that previously corresponded to a stable clock domain under similar conditions.

In one aspect of the disclosure, the state machine 104 disables the clock domain signal C1 by gating the clock domain signal C1 to a logic low. The state machine 104 disables the clock domain signal C1 based on or in response to the pulse count from the frequency stabilization counter 106. In one aspect of the disclosure, the pulse count may indicate whether the clock domain signal C1 has achieved actual stability. The actual stability of the clock domain may be based on a history of pulse counts that previously indicated when the clock domain has achieved actual stability. For example, the clock domain signal C1 may be enabled after the current pulse count matches a prior pulse count that indicated when the clock domain is actually stable. In some aspects of the disclosure, the current clock pulse count may indicate when the clock domain is actually stable when the current pulse count meets a threshold pulse count.

In one aspect of the disclosure, the state machine 104 is arranged to receive an input request enable signal E4 that corresponds to a request for a clock domain signal for a target resource. The state machine may also receive a pulse count indication from the frequency stabilization counter 106. The state machine 104 is further arranged to output a gated clock signal C_{g} to enable the clock domain signal to be sent to the target resource based on the pulse count indication from the frequency stabilization counter 106, the clock domain signal and the condition of the state machine internal clock. For example, pulse count indication may be used to alert the state machine 104 when the clock domain signal C1 achieves actual stability. In response to the alert, the state machine 104 may generate the gated clock signal C_{g}. The gated clock signal C_{g} may be based on a negative edge triggered implementation.

The logic circuits of the asynchronous clock enable system 100 may include flip flops 108, 110 and 112. The logic circuits of the asynchronous clock enable system 100 may also include logic AND gates 114, 116, 118, 120 and logic OR gates 122 and 124. The asynchronous clock enable system 100 generates an actual stable output clock signal C3 for the one or more target resources in an integrated circuit system. To generate the actual stable output clock signal C3, the asynchronous clock enable system may receive one or more input requests (e.g., IP 1, IP 2, IP 3) for a clock signal to operate a target resource. The one or more input requests may be received at the OR logic gate 122. An input request IP 1 of the one or more input requests IP 1, IP 2, IP 3 may be received at an input of the OR logic gate 122. The output of the OR logic gate 122 may be based on the received input IP 1, which may be selected from the one or more input requests IP 1, IP 2, IP 3 for processing. One or more clock prerequisites may be specified in order to process the selected input request. In one aspect, the selected input request, e.g., IP 1, which corresponds to an output of the logic OR gate 122 may be received at an input of the AND logic gate 114 in conjunction with a clock prerequisite signal Cₚ. In other words, the selected input request, IP 1, is “ANDed” with the clock prerequisite signal Cₚ at the input of the AND logic gate 114. The output of the AND logic gate 114 may be deemed an input enable signal E1 for the state machine 104. The input enable signal E1 may be forwarded to an input of the flip flop 110 as well as an input of the AND logic gate 116.

The clock domain signal C1 may be generated upon power up of the integrated system or when at least a portion of the integrated circuit system is awakened from a sleep mode. Under these conditions, the clock domain signal C1 may be unstable for a time period. The instability may be due to the time delay associated with a warm-up period of an oscillation device, e.g., crystal, of the clock domain. For example, when power is initially applied to the clock domain, the crystal of the clock domain begins to warm-up over a period of time where the crystal operates at less than normal operating frequency and error range. The oscillations grow over time and finally reach a stable or steady state value or amplitude.

In one aspect of the disclosure, the clock generation block 102 may include a clock stability device (not shown) to generate a clock stability indication signal Cₛ when the clock domain achieves an initial stable state or when the clock domain is glitchless or substantially glitchless. The initial stable state indicated by the clock stability indication signal Cₛ, however, may not be enough stability for operation of the target resource. As a result, the asynchronous clock enable system 100 incorporates the implementation of the state machine 104 in conjunction with the frequency stabilization counter 106 to determine when the clock domain achieves actual stability.

The clock stability indication signal Cₛ may be received at an input of the AND logic gate 120 in conjunction with the clock domain signal C1. In other words, the clock stability indication signal Cₛ is “ANDed” with the clock domain signal C1 at the input of the AND logic gate 120. The output of the AND logic gate 120 is an initially stable or substantially glitchless clock domain signal C2. For example, the clock domain signal is substantially glitchless when the clock stability indication signal Cₛ is high. The glitchless clock domain signal C2 may be forwarded to an input of the flip flops 110, 112 (e.g., D flip flop) and the state machine 104. The glitchless clock domain signal C2 may be the clock pulse of the flip flop 110, 112.

The flip flop 110 may receive the input enable signal E1 that corresponds to the output of the AND logic gate 114. The input enable signal E1 may be directed to the D input of the flip flop 110 to set or reset the flip flop 110. For example, if there is a high or logic 1 on the D input when the clock pulse is applied, the flip-flop 110 sets and stores a logic 1. If there is a low or logic 0 on the D input when the clock pulse is applied, the flip-flop 110 resets and stores a 0. The output of the flip flop 110 is forwarded to the flip flop 112 for processing.

The output of the flip flop 110 may correspond to the D input of the flip flop 112 to set or reset the flip flop 112. For example, if there is a high or logic 1 on the D input when the clock pulse is applied, the flip-flop 112 sets and stores a logic 1. If there is a low or logic 0 on the D input when the clock pulse is applied, the flip-flop 112 resets and stores a logic 0. The output of the flip flop 112 is forwarded to the state machine 104 for processing. The output of the flip flop 112 may be deemed an input request enable signal E4 that indicates a request for clock domain signal for a target resource.

When the state machine 104 receives the input request enable signal E4, the state machine 104 determines whether the glitchless clock domain signal C2 has achieved an actual stable operation based on a pulse count of the glitchless clock domain signal C2. If the state machine determines that the glitchless clock domain signal C2 has achieved actual stability, the actually stable clock domain signal is forwarded to the target resource according to the input request. In one aspect of the disclosure, the state machine 104 may generate the gated clock signal C_{g} to enable the clock domain signal based on whether the glitchless clock domain signal C2 achieved the actual stability. The gated clock signal C_{g} may be received at an input of the AND logic gate 118 in conjunction with the glitchless clock domain signal C2. In other words, the gated clock signal C_{g} is “ANDed” with the glitchless clock domain signal C2 at the input of the AND logic gate 118. The output of the AND logic gate 118 is the actual stable output clock signal C3, which provides a clock signal for the target resource when the clock domain signal has achieved actual stability.

The asynchronous clock enable system 100 may incorporate a feedback loop to enable or disable the clock domain of the clock generation block 102. The enabling or disabling of the clock domain may not be synchronized with the enabling or disabling of the state machine 104. This feature may be achieved because the state machine internal clock operates independent or asynchronous relative to the clock domain. In one aspect of the disclosure, the state machine 104 may generate a state machine based disable signal Cd that may cause the clock domain to be disabled after a target resource no longer desires the clock domain signal or upon an interruption in the input request. In this case, the state machine 104 may generate the state machine based disable signal Cd and forward the state machine based disable signal Cd to an input of the AND logic gate 116. The AND logic gate may also receive the input enable signal E1. The state machine based disable signal Cd is “ANDed” with the input enable signal E1 at the input of the AND logic gate 116. The resulting output of the AND logic gate 116 is an output enable signal E2 to set the flip flop 108 to a logic high or logic low.

An output E3 of the flip flop 108 may be selected through the OR logic gate 124. The output E3 may cause the clock generation block 102 to be disabled. The state machine 104 may also generate the clock C4 for the flip flop 108. In this configuration, the clock pulse input of the flip flop 108 may receive the clock C4 from the state machine 104. In this regard, the flip flop 108 is asynchronous relative to the flip flops 110 and 112 that receive clock pulse signals from the clock domain (i.e., the glitchless clock domain signal C2). In some instances, the state machine 104 may generate a clear pulse signal to clear the clock pulse of the flip flop. Clearing the clock pulse for the flip flop 108 may occur when there are interruptions between a first input request and a second input request. In some instances, the D input of the flip flop 108 may be set to a ground.

Similarly, a clock enable signal E5 generated by the state machine 104 can cause the clock generation block 102 to enable or continue to be enable the clock generation block even when there are no requests for a clock domain to operate a target resource. The clock enable signal E5 may be received at an input of the OR logic gate 124 in conjunction with the resulting output E3 of the flip flop 108. In other words, the clock enable signal E5 is “ORed” with the resulting output E3 of the flip flop 108 at the input of the OR logic gate 124. The output of the OR logic gate 124 is a clock generator enable/disable signal E6 that enables/disables the clock domain depending on the input signal selected at the OR gate 124.

### Clock Enabled

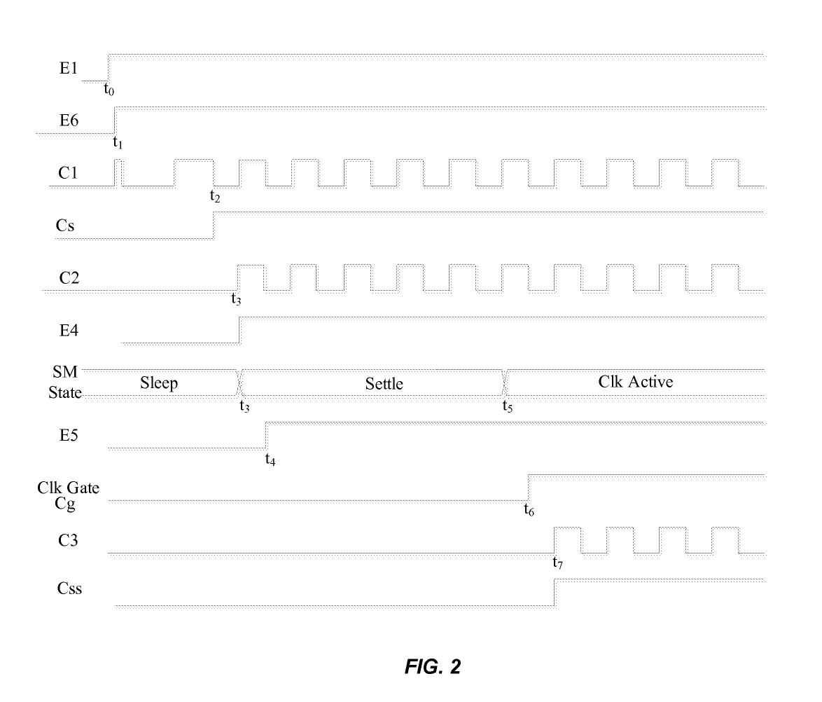

FIG. 2 illustrates exemplary timing diagram of various timing signals for enabling a clock of an asynchronous clock enable system of FIG. 1 according to one or more aspects of the present disclosure.

The timing diagram corresponds to the input enable signal E1, the clock generator enable/disable signal E6, the clock domain signal C1, the clock stability indication signal Cₛ, the glitchless clock domain signal C2, the input request enable signal E4, state machine internal clock state, the clock enable signal E5, the gated clock signal C_{g}, the actual stable output clock signal C3 and the gated output clock stability signal C_{gs}.

The input enable signal E1 provided to the input of the flip flop 110 switches between logic zero and logic one. For example, the input enable signal E1 switches from a logic low to a logic high at time t₀ when an input request for a clock domain to operate a target resource is received, as shown in FIG. 2.

The clock generator enable/disable signal E6 provided to the input of the clock generation block 102 switches between logic zero and logic one. For example, the clock generator enable/disable signal E6 switches from a logic low (e.g. when disabled) to a logic high (e.g., when enabled) at time t₁, as shown in FIG. 2. This switch may occur when the clock enable signal E5 is selected at the OR logic gate 124.

The clock domain signal C1 provided to the input of the AND logic gate 120 switches between logic zero and logic one. For example, when the clock domain of the clock generation block 102 is powered on (e.g., when the clock domain is enabled at time t=t₁), the applied voltage creates noise or glitches in the oscillations and causes a crystal of the clock domain to begin oscillating. The voltage across the crystal increases with time because the crystal acts as a capacitor that is being charged. As a result, the frequency or amplitude of the clock domain signal C1 increases with time until the clock domain achieves the initial stable operation, at t=t₂, as illustrated in FIG. 2.

The clock stability indication signal Cs provided to the input of the AND logic gate 120 switches between logic zero and logic one. For example, the clock stability indication signal Cs switches from a logic low (e.g. when the clock domain signal C1 is unstable) to a logic high (e.g. when the clock domain signal C1 is initially stable) at time t=t₂ when the clock domain signal is substantially glitch free, as shown in FIG. 2.

The glitchless clock domain signal C2 provided to the input of the AND logic gate 118 and the clock pulse inputs of the flip flops 110 and 112, switches between logic zero and logic one. The glitchless clock domain signal C2 may be delayed from the time that the clock domain is powered up. The glitchless clock domain signal C2 may be delayed to account for the delay associated with the initial stable operation of the clock domain signal C1. In this case, the glitchless clock domain signal C2 is initiated at time, t₃, as shown in of FIG. 2. When the initial stable operation of the clock domain signal C1 is initiated at time, t₂, a clock switching operation is initiated by turning on or activating the glitchless clock domain signal C2 at time t₃.

The input request enable signal E4 provided to the input of the state machine 104 switches between logic zero and logic one. For example, the input request enable signal E4 switches from a logic low to a logic high at time t₃ when an input request for a clock domain to operate a target resource is received and when the glitchless clock domain signal C2 is enabled or activated, as shown in FIG. 2. As noted, the glitchless clock domain signal C2 provides the clock pulse for the flip flops 110 and 112 that allows the input request enable signal E4 to be forwarded to the state machine 104.

The clock gating device (e.g., the state machine in conjunction with the frequency stabilization counter) may activate/deactivate a target resource by gating the clock signal provided to the target resource. The clock gating device passes the clock signal of the clock domain (e.g., glitchless clock domain signal C2) to the target resource when the state machine internal clock achieves an active state. Therefore, even though the clock domain of the clock generation block achieves an initial stable operation at time t₃, the clock domain signal is not forwarded to the target resource until the state machine internal clock is active. Conversely, the clock gating device inhibits or blocks the clock domain signal from reaching the target resource when the state machine internal clock is inactive. For example, the state machine internal clock is inactive when in a sleep mode, as illustrated in FIG. 2.

When the state machine internal clock is powered on or wakes up from the sleep mode at time t₃, an applied voltage causes a crystal of the state machine internal clock to start to oscillate. In one aspect, the voltage may be applied to the state machine internal clock when the state machine 104 receives the input request enable signal E4 or in response to other independent activation implementation. For example, the state machine internal clock is powered on or wakes up at time t₃, which corresponds to the time the input request enable signal E4 switches from a logic low to a logic high. The voltage across the crystal of the state machine internal clock increases with time because the crystal acts as a capacitor that is being charged. As a result, the frequency or amplitude of the crystal of the state machine internal clock increases with time until the crystal of the state machine internal clock achieves an active state at time t₅, as illustrated in FIG. 2. The period between the wake up time t₃ and the activation time t₅ of the state machine internal clock is a settling period of the state machine internal clock, as shown in FIG. 2.

The clock enable signal E5 provided to the input of the OR logic gate 124 switches between logic zero and logic one. For example, the clock enable signal E5 switches from a logic low to a logic high at time t₄ when the state machine internal clock wakes up from the sleep mode, as shown in FIG. 2. In one aspect of the disclosure, the time t₄ corresponds to a next clock signal after the state machine internal clock wakes up at time t₃.

The gated clock signal C_{g} provided to the input of the AND logic gate 118 switches between logic zero and logic one. For example, the gated clock signal Cg switches from a logic low to a logic high at time t₆ after the state machine internal clock achieves an active state, as shown in FIG. 2. In one aspect of the disclosure, the time t₆ corresponds to a time after the state machine internal clock enters the active state.

The actual stable output clock signal C3 provided to the target resource, switches between an activated or enabled state and a deactivated or disabled state. For example, the actual stable output clock signal C3 is enabled at time t₇ when the glitchless clock domain signal C2 achieves stability. In one aspect of the disclosure, the time t₇ corresponds to a delay, such as a full clock cycle after the gated clock signal Cg switches from a logic low to a logic high at time t₆.

The actual stable state of the clock domain may be indicated by a stable state signal Css generated by the asynchronous clock enable system (e.g., the clock gating device). The stable state signal Css corresponds to the actual stable state of the clock domain in response to an input request to operate the target resource. The stable state signal Css may be activated when the state machine 104 enters an active mode (i.e., at time t7) in response to the generation of the input request.

### Clock Disabled

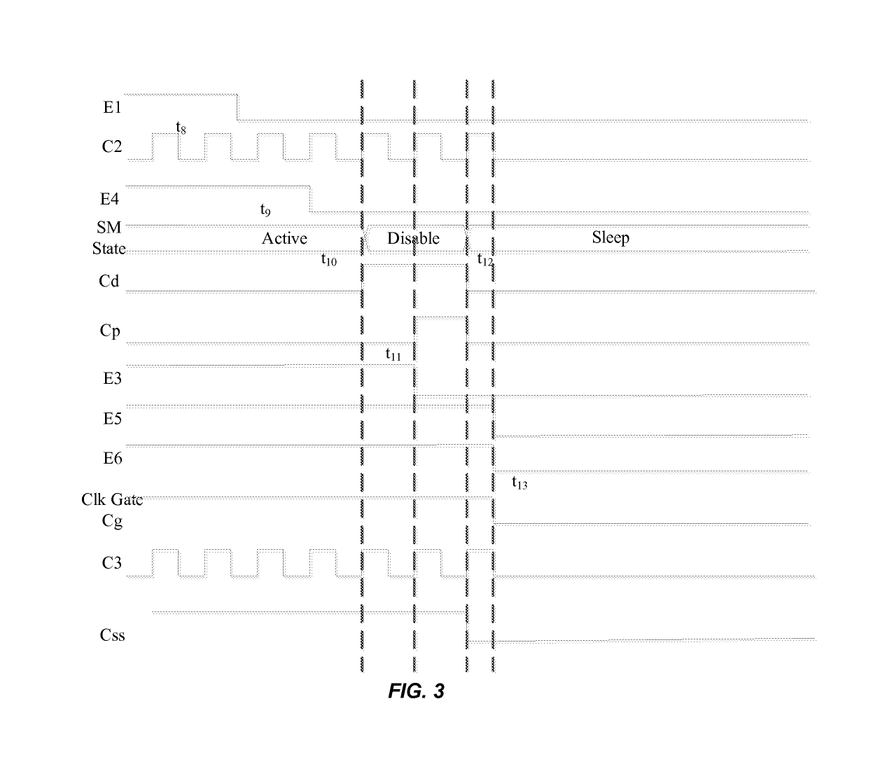

FIG. 3 illustrates exemplary timing diagram of various timing signals for disabling a clock of an asynchronous clock enable system of FIG. 1 according to one or more aspects of the present disclosure.

The timing diagram of FIG. 3 includes the input enable signal E1, the clock generator enable/disable signal E6, the glitchless clock domain signal C2, the input request enable signal E3, the input request enable signal E4, state machine internal clock state, the state machine based disable signal Cd, the clear pulse signal Cₚ, the clock enable signal E5, the gated clock signal C_{g}, the actual stable output clock signal C3, and the gated output clock stability signal C_{gs}.

As noted, the input enable signal E1 provided to the input of the flip flop 110 switches between logic zero and logic one. For example, the input enable signal E1 switches from a logic high to a logic low at time t₈ when there are no input requests for a clock domain to operate a target resource, as shown in FIG. 3.

As a result of the lack of input request (i.e., when the input enable signal E1 switches to a logic low), the input request enable signal E4 may also switch from a logic high to a logic low at time t₉. In this case, the switch in logic state of the input request enable signal E4 may be delayed relative to that of input enable signal E1. The delay may correspond to one or more clock cycles.

The absence of a request for a clock domain to operate the target resource may prompt the state machine 104 to deactivate or disable the state machine internal clock. In this case the absence of the request corresponds to the disabling of the input request enable signal E4 (i.e., when the input request enable signal E4 switches to a logic low). The start of the disabling of the state machine internal clock may be delayed relative to the switching of the logic state of the input request enable signal E4. The delay may correspond to one or more clock cycles. For example, disabling the state machine internal clock may be initiated at time t₁₀, which is a clock cycle later than the time t₉ when the input request enable signal E4 switched to a logic low. The disabling of the state machine internal clock may extend to time t₁₂, after which the state machine internal clock enters a sleep mode. The state machine enters into sleep mode if the lack of input requests (e.g., input request enable signal E4 is at a logic low) at the end of the disabling period (i.e., at time t₁₂) persists after the state machine 104 is disabled.

The state machine may generate the state machine based disable signal Cd concurrent with the start time (at time t₁₀) and end time (at time t₁₂) for disabling the state machine internal clock, as shown in FIG. 3. The end (at time t₁₂) for disabling the state machine internal clock corresponds to the start of the sleep mode of the state machine internal clock.

The state machine based disable signal Cd facilitates the enabling/disabling of the clock domain signal. For example, the clock generator enable/disable signal E6 that is based on the state machine based disable signal Cd is forwarded to the clock generation block 102 to disable/enable the clock domain (e.g., glitchless clock domain signal C2).

The clock enable signal E5 also facilitates the enabling/disabling of the clock domain signal. For example, the clock generator enable/disable signal E6 that is based on the clock enable signal E5 is forwarded to the clock generation block 102 to enable/disable the clock domain (e.g., glitchless clock domain signal C2).

The state machine 104 may generate a clear pulse signal Cₚ to clear clock pulses generated by the state machine 104. The clear pulse signal Cₚ may be generated in concurrence with the state machine based disable signal C_{d} to facilitate disabling the clock domain and/or the state machine internal clock. For example, the clock pulse signal may be initiated (at time t₁₁) a full clock cycle after the state machine based disable signal C_{d} is initiated. The clear pulse signal Cₚ, however, may end at the same time t₁₂ as the state machine based disable signal C_{d}. The clear pulse signal Cₚ may clear the clock pulse of the flip flop 108 causing the clock disable signal E3 to be disabled at the start of the clear pulse signal (i.e., at time t₁₁).

The clock generator enable/disable signal E6 may be enabled or disabled in response to state machine based disable signal C_{d} and the clear pulse signal Cₚ. Disabling the clock generator enable/disable signal E6 causes the clock generation block 102 and subsequently the clock domain to be disabled.

In one aspect of the disclosure, the clock domain is disabled when the clock generator enable/disable signal E6 is at a logic low and enabled when at a logic high. Because the clock generator enable/disable signal E6 is a selected output of the OR logic gate 124, the clock generator enable/disable signal E6 is disabled only when both the clock enable signal E5 and the clock disable signal E3 (that is based on the state machine based disable signal C_{d}) are disabled or at a logic low. For example, although the clock disable signal E3 of FIG. 3 is disabled at time t₁₁, which corresponds to the start of the clear pulse signal Cₚ, the clock domain (i.e. glitchless clock domain signal) and/or the actual stable output clock signal C3 are only disabled when both the clock disable signal E3 and the clock enable signal E5 are disabled (i.e., logic low.) When both the clock disable signal E3 and the clock enable signal E5 are at a logic low (at time t₁₃), the clock generator enable/disable signal E6 is disabled. As a result, the clock generation block 102 is disabled such that the glitchless clock domain signal C2 is disabled at time t₁₃. Because the gated clock signal C_{g} depends on the state machine internal clock, the gated clock signal C_{g} is also disabled at time t₁₃ to correspond to the state machine internal clock being disabled.

The actual stable state of the clock domain may be indicated by a stable state signal Css generated by the asynchronous clock enable system (e.g., the clock gating device). The stable state signal Css corresponds to the actual stable state of the clock domain in response to the input request. The stable state signal Css may be terminated concurrently with the time the state machine enters a sleep mode (i.e., at time t₁₂) in response to the termination of the input request.

As noted, the asynchronous clock enable system 100 may receive one or more input requests (e.g., IP 1, IP 2, IP 3) for a clock signal to operate a target resource. The input requests may originate from different sources. In some implementations, an input source (IP 1) may disable or deactivate the state machine 104 and the corresponding state machine internal clock before another input source (IP 2) issues a request for a clock domain to operate a target resource. This may cause a glitch that may prolong for one, two or three clock cycles. FIGS. 1, 2 and 3 are timing diagrams that illustrate the glitches caused by these implementations.

### Input Request Synchronizers Low for a Single Clock Period

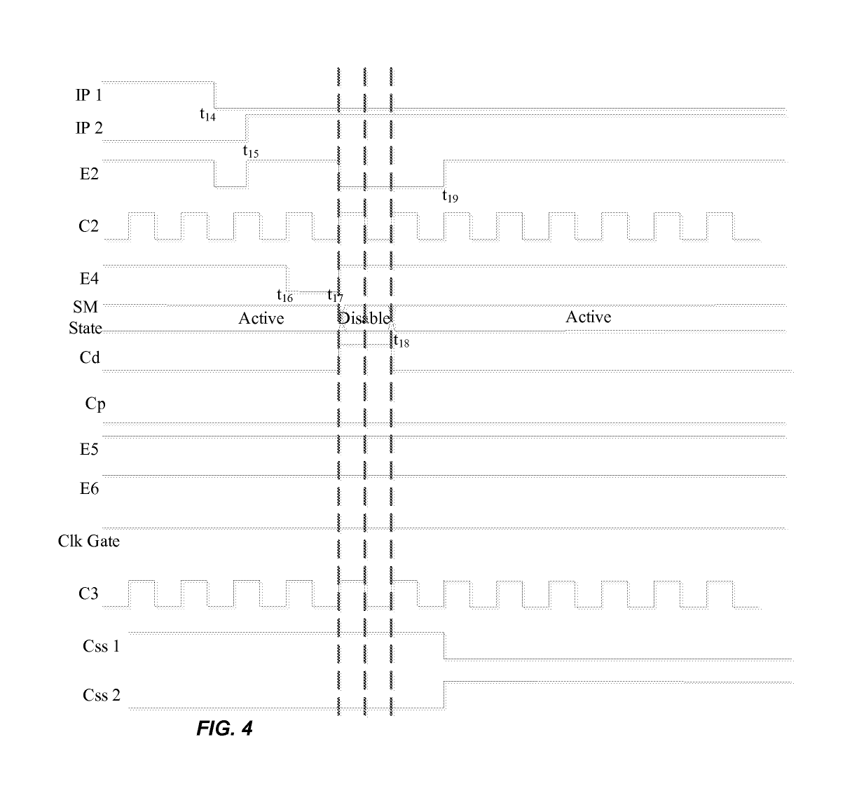

FIG. 4 illustrates exemplary timing diagram of various timing signals of the asynchronous clock enable system of FIG. 1 for a single clock glitch according to one or more aspects of the present disclosure.

The single clock glitch occurs when there is a gap in the input requests that causes the state machine 104 and the corresponding state machine internal clock to deactivate for a single clock cycle. For example, a first input request IP 1 may terminates or deactivate at time t₁₄. A second input request IP 2 may be initiated at a later time t₁₅ causing a gap between the first and the second input requests that is less than or equal to a single clock cycle. In this case, the glitch caused by the temporary interruption of the state machine is filtered out by the logic of the asynchronous clock enable system 100. As a result, the actual stable output clock signal C3 and the glitchless clock domain signal C2 are substantially unchanged or unaffected by the single clock glitch, as shown in FIG. 4.

The termination of the first input request IP 1 may cause the output enable signal E2 to be disabled at time t₁₄up to time t₁₅. At time t₁₅, the output enable signal E2 is reactivated when the second input request IP 2 is initiated. Because of the gap (e.g., single clock cycle gap) between the first and the second input requests IP 1 and IP 2, the input request enable signal E4 may also be temporarily deactivated or disabled. For example, the input request enable signal E4 may be disabled for a full clock cycle between time t₁₆ and t₁₇. The input request enable signal E4 is reactivated at time t₁₇ to account for the second input request IP 2. As a result of the deactivation of the input request enable signal E4, the state machine is temporarily disabled between time t₁₇ and t₁₈ that is a full clock cycle later than the period of deactivation of the input request enable signal E4. The state machine, however, does not initiate a sleep mode because the state machine is only disabled for a single clock cycle, which is not enough time for the state machine to enter into sleep mode.

In some aspects, the state machine specifies two clock cycles to achieve sleep mode. Thus, rather than entering a sleep mode after being disabled for a single clock cycle, the state machine is re-activated starting at time t₁₈.

In response to the state machine 104 being temporarily disabled, the state machine 104 generates a concurrent state machine based disable signal C_{d} between the time t₁₇ and t₁₈. The activation of the state machine based disable signal C_{d} causes the output enable signal E2 to be disabled at time t₁₇ up to time t₁₉. The difference between the end time t₁₈ of the disable signal C_{d} and the end time t₁₉ i.e., the end of the deactivation period of the output enable signal E2) may be the result of a specified or unspecified delay in the asynchronous clock enable system 100.

In this instance, the state machine does not generate a clear pulse signal Cₚ because of the state machine is only deactivated for a single clock cycle. The clear pulse signal Cₚ is generally delayed at least a clock cycle from the start of the state machine deactivation. For example, when the deactivation period is two clock cycles, as shown in FIG. 3, the clear pulse signal Cₚ is initiated half way through the deactivation period and ends at the same time as the deactivation period. In the current case, however, the clear pulse signal Cₚ is not activated because the state machine is reactivated after the single clock cycle deactivation period rather than being disabled for two clock cycles before entering sleep mode.

Under the conditions of the single clock glitch, the temporary interruption of the state machine internal clock does not affect the operation of the glitchless clock domain signal C2 or the actual stable output clock signal C3, as shown in FIG. 4. For example, although the state machine is temporarily disabled, the state machine 104 does not enter a sleep mode. Instead, the state machine is quickly activated after a single clock cycle. Reactivating the state machine over the single clock cycle does not allow enough delay for the state machine to enter into sleep mode. As a result, the clock enable signal E5 as well as the clock generator enable/disable signal E6 stays active or at a logic high. Consequently, the clock generation block 102 is enabled by the clock generator enable/disable signal E6 even though the resulting output E3 may temporarily undergo a deactivation period due to the temporary interruption of the state machine 104.

The actual stable state of the clock domain may be indicated by a stable state signal Cₛₛ generated by the asynchronous clock enable system (e.g., the clock gating device). A first stable state signal Cₛₛ 1 corresponds to the actual stable state of the clock domain in response to the first input request IP 1. The first stable state signal C_{ss 1} may be terminated (i.e., at time t₁₉) in response to the state machine being disabled (at time t₁₇ to t₁₈) and in response to the termination of the first input request IP 1. A second stable state signal Cₛₛ 2 corresponds to the actual stable state of the clock domain in response to the second input request IP 2. The second stable state signal C_{ss 2} may be activated (i.e., at time t₁₉) in response to the state machine 104 being activated (at time t₁₈) and in response to the generation of the second input request IP 2.

### Input Request Synchronizers Low for Two Clock Periods

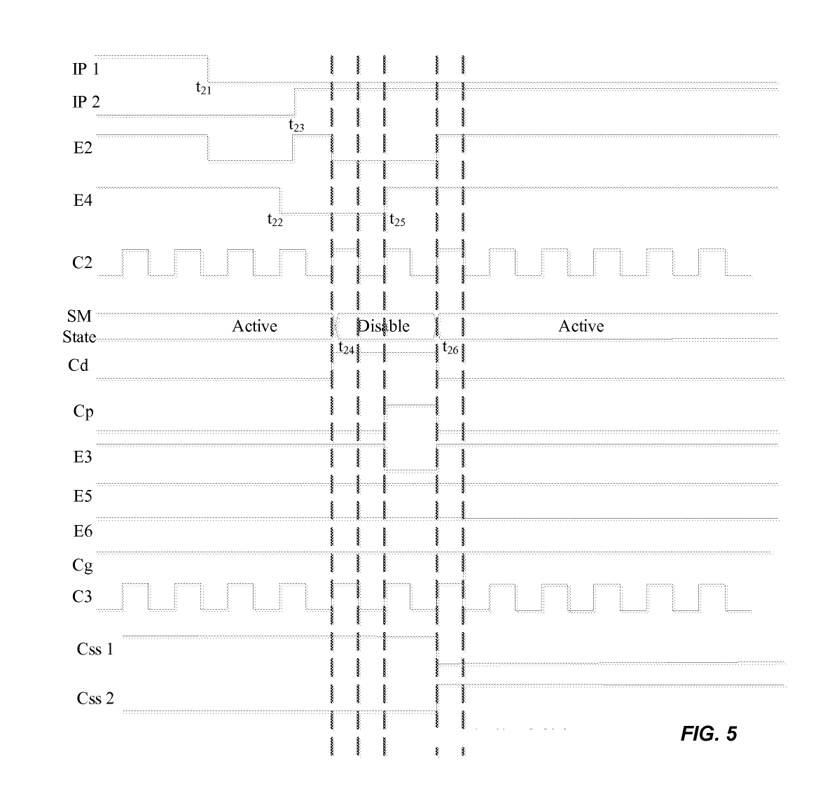

FIG. 5 illustrates exemplary timing diagram of various timing signals of the asynchronous clock enable system of FIG. 1 for a double clock glitch according to one or more aspects of the present disclosure.

While the timing diagram for the double clock glitch is similar to those of the single clock glitch, the double clock glitch occurs when there is a gap in the input requests that causes the state machine 104 and the corresponding state machine internal clock to deactivate for two clock cycles. For example, the gap between the first input request IP 1 and the second input request IP 2 is more than a single clock cycle but less than or equal to two clock cycles. This gap (i.e., between time t₁₄ and t₁₅) between the first and the second input requests IP 1 and IP 2 is greater than a single clock cycle but less than or equal to two clock cycles. Similar to the single clock glitch, the double clock glitch caused by the temporary interruption of the state machine is filtered out by the logic of the asynchronous clock enable system 100. As a result, the actual stable output clock signal C3 and the substantially glitchless clock domain signal C2 are substantially unchanged or unaffected by the double clock glitch, as shown in FIG. 5.

Similar to the single clock glitch, the termination of the first input request IP 1 of the double clock glitch may cause the output enable signal E2 to be disabled at time t₂₁ (when IP 1 ends) up to time t₂₃. At time t₂₃, the output enable signal E2 is reactivated when the second input request IP 2 is initiated. Because of the gap (e.g., double clock cycle gap) between the first and the second input requests IP 1 and IP 2, the input request enable signal E4 may also be temporarily deactivated or disabled. For example, the input request enable signal E4 may be disabled for a double clock cycle between time t₂₂ and t₂₅. The input request enable signal E4 is reactivated at time t₂₅ to account for or in response to the second input request IP 2. As a result of the deactivation of the input request enable signal E4, the state machine 104 is temporarily disabled between time t₂₄ and t₂₆ over two clock cycles. The state machine 104, however, does not enter into a sleep mode because the state machine is only disabled for a two clock cycles. In this case, two clock cycles is not enough time for the state machine to enter into the sleep mode, especially when the second input request IP 2 to activate the state machine occurs prior to or at the end of the two clock cycles. Thus, rather than entering a sleep mode after being disabled for two clock cycles, the state machine is re-activated starting at time t₂₆.

In response to the state machine 104 being temporarily disabled, the state machine 104 generates a concurrent state machine based disable signal C_{d} between the time t₂₄ and t₂₆. The activation of the state machine based disable signal C_{d} causes the output enable signal E2 to be disabled at time t₂₄ up to time t₂₆.

Unlike the single clock glitch, however, the state machine in the two clock glitch generates a clear pulse signal Cₚ between the time t₂₅ and t₂₆. The clear pulse signal Cₚ is generally delayed at least a clock cycle from the start of the disable mode of the state machine. For example, when the disable mode is two clock cycles, the clear pulse signal Cₚ is initiated half way through the disable mode (i.e., at t₂₅) and ends at the same time as the deactivation period (i.e., at t₂₆). The activation of the clear pulse signal Cₚ (i.e., between times t₂₅ and t₂₆) is concurrent with the deactivation of the resulting output E3, which is based at least in part on the activation/deactivation of the state machine based disable signal C_{d}.

Similar to the single clock glitch, the temporary interruption of the state machine internal clock of the double clock glitch does not affect the operation of the glitchless clock domain signal C2 or the actual stable output clock signal C3. For example, although the state machine is temporarily disabled, the state machine 104 does not enter a sleep mode. Instead, the state machine is quickly activated after a double clock cycle. Reactivating the state machine, in this instance, does not allow enough delay for the state machine to enter into the sleep mode. As a result, the clock enable signal E5 as well as the clock generator enable/disable signal E6 stays active or at a logic high. Consequently, the clock generation block 102 is enabled by the clock generator enable/disable signal E6 even though the resulting output E3 may temporarily undergo a deactivation period due to the temporary interruption of the state machine 104.

The actual stable state of the clock domain may be indicated by a stable state signal Cₛₛ generated by the asynchronous clock enable system (e.g., the clock gating device). A first stable state signal Cₛₛ 1 corresponds to the actual stable state of the clock domain in response to the first input request IP 1. The first stable state signal C_{ss 1} may be terminated (i.e., at time t₂₆) in response to the state machine being disabled (at time t₂₄ to t₂₆) and in response to the termination of the first input request IP 1. A second stable state signal Cₛₛ 2 corresponds to the actual stable state of the clock domain in response to the second input request IP 2. The second stable state signal C_{ss 2} may be activated (i.e., at time t₂₆) in response to the state machine 104 being activated (at time t₂₆) and in response to the generation of the second input request IP 2.

### Input Request Synchronizers Low for Three Clock Periods

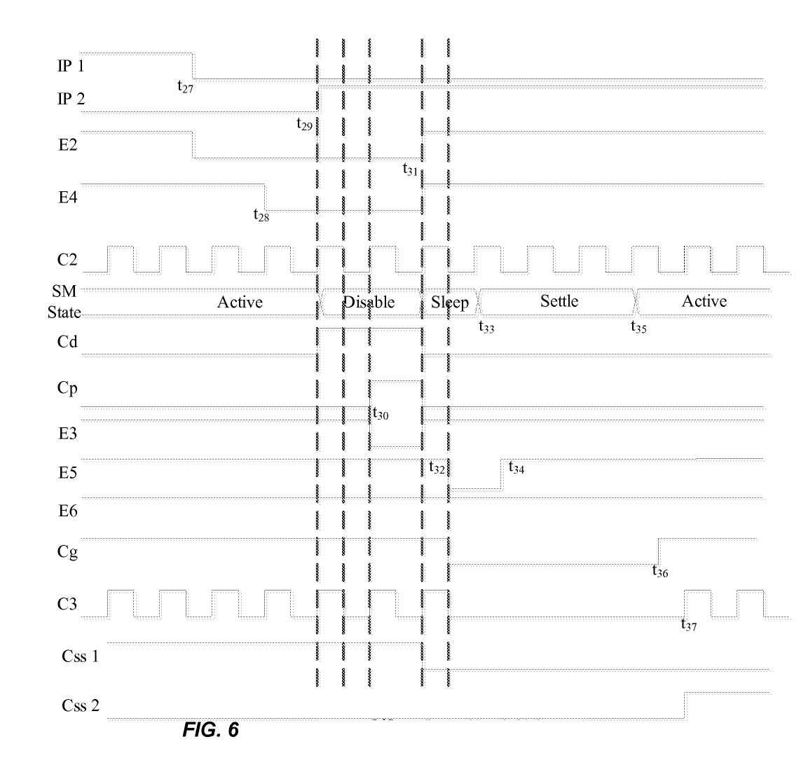

FIG. 6 illustrates exemplary timing diagram of various timing signals of the asynchronous clock enable system of FIG. 1 for a triple clock glitch according to one or more aspects of the present disclosure.

The triple clock glitch occurs when there is a gap in the input requests that causes the state machine 104 and the corresponding state machine internal clock to deactivate for a triple clock cycle. For example, the gap between the first input request IP 1 and the second input request IP 2 is more than two clock cycles but less than or equal to threes clock cycle. This gap (i.e., between time t₂₇ and t₂₉) between the first and the second input requests IP 1 and IP 2 is greater than two clock cycles but less than or equal to three clock cycles. Unlike the single clock glitch, the triple clock glitch caused by the temporary interruption of the state machine (i.e., the state machine being disabled and temporarily entering a sleep mode) may cause at least some of the clock resources of the asynchronous clock enable system 100 to be disabled and the state machine to enter into a sleep mode. For example, the actual stable output clock signal C3 may be temporarily disabled while the substantially glitchless clock domain signal C2 is substantially unchanged or unaffected by the triple clock glitch.

The termination of the first input request IP 1 (at time t₂₇) of the of the triple clock glitch may cause the output enable signal E2 to be disabled at time t₂₇ up to time t₃₁. At time t₃₁, the output enable signal E2 is reactivated in response to the second input request IP 2 being initiated. Because of the gap (e.g., triple clock cycle gap) between the first and the second input requests IP 1 and IP 2, the input request enable signal E4 may also be temporarily deactivated or disabled. For example, the input request enable signal E4 may be disabled for a triple clock cycle between time t₂₈ and t₃₁. The input request enable signal E4 is reactivated at time t₃₁ to account for or in response to the second input request IP 2. As a result of the deactivation of the input request enable signal E4, the state machine 104 is temporarily disabled between times t₂₉ and t₃₁ over two clock cycles. The state machine 104 enters a sleep mode between time t₃₁ and t₃₃ over a single clock cycle after the state machine is disabled. When the state machine 104 wakes up from the sleep mode due to the initiation of the second input request IP 2, the sate machine internal clock warms up before achieving stability or entering an active state. The warm up period continues until the clock settles at a desired settling signal. The period of warm up of the state machine internal clock may be deemed a settle mode. The settle mode may be between times time t₃₃ and t₃₅. The state machine 104 may be reactivated at the end of the sleep mode at time t₃₅ to account for the initiated second input request IP 2.

In response to the state machine 104 being temporarily disabled (i.e., between t₂₉ and t₃₁), the state machine 104 generates a concurrent state machine based disable signal C_{d} between the time t₂₉ and t₃₁. The generation of the state machine based disable signal C_{d} prolongs the period that the output enable signal E2 is disabled. For example, the generation of state machine based disable signal C_{d} may cause the output enable signal E2 to be disabled between the period of time t₂₉ up to time t₃₁. Thus, the state machine based disable signal C_{d} accounts for a second half of the time that the output enable signal E2 is disabled. The first half is concurrent with the gap between the first input request IP 1 and the second input request IP 2.

Similar to the double clock glitch, the state machine 104 in the triple clock glitch generates a clear pulse signal Cₚ between the time t₃₀ and t₃₁. The clear pulse signal Cₚ is delayed at least a clock cycle from the start of the disable mode of the state machine 104. For example, when the disable mode is two clock cycles, the clear pulse signal Cₚ is initiated half way through the disable mode (i.e., at t₃₀) and ends at the same time as the disable mode (i.e., at t₃₁). The activation of the clear pulse signal Cₚ (i.e., between times t₃₀ and t₃₁) is concurrent with the deactivation of the resulting output E3, which is based at least in part on the activation/deactivation of the state machine based disable signal C_{d}.

When the state machine 104 enters the sleep mode, the state machine 104 disables the clock enable signal E5 temporarily. In some aspects of the disclosure, the clock enable signal E5 is disabled between time t₃₂ and time t₃₄. The clock enable signal E5 is enabled at time t₃₄ after the state machine 104 is awakened from sleep mode. The initiation of the disable mode of the clock enable signal E5 (i.e., at time t₃₂) may be concurrent with the initiation of a disable mode of the gated clock signal C_{g}. The disabled mode of the gated clock signal C_{g}, however, may continue until the state machine regains it active mode (i.e., at time t₃₆ after the active mode of the state machine 104 is initiated at t₃₅).

Similar to the single clock glitch and the double clock glitch, the temporary interruption of the state machine internal clock of the triple clock glitch does not affect the operation of the glitchless clock domain signal C2. Although the clock enable signal E5 is temporarily disabled during the temporary interruption of the state machine 104, the clock generator enable/disable signal E6, however, stays active or stays at a logic high. The clock generator enable/disable signal E6 maintains an active high because the two inputs (i.e., the clock enable signal E5 and the resulting output E3) to the OR logic gate 124 are not concurrently at an active low. As a result, the output of the OR logic gate 124, which is the clock generator enable/disable signal E6, is always at an active high to enable the glitchless clock domain signal C2 without clock interruptions. Unlike the single clock glitch and the double clock glitch, however, the actual stable output clock signal C3 of the triple clock glitch is subject to clock interruptions. For example, the gated clock signal C_{g} that enables the glitchless clock domain signal C2 to the target resource is temporarily disabled or interrupted between times t₃₂ and t₃₆. The interruption of the gated clock signal C_{g} causes the actual stable output clock signal C3 to the target resource to be interrupted between times t₃₂ and t₃₇.

During the triple clock glitch, the clock operation of the state machine 104 is temporarily interrupted during a gap between the first input request IP 2 and the second input request IP 2.

The actual stable state of the clock domain may be indicated by a stable state signal Cₛₛ generated by the asynchronous clock enable system (e.g., the clock gating device). A first stable state signal Cₛₛ 1 corresponds to the actual stable state of the clock domain in response to the first input request IP 1. The first stable state signal C_{ss 1} may be terminated concurrently with the time the state machine enters a sleep mode (i.e., at time t₃₁) in response to the termination of the first input request IP 1. A second stable state signal Cₛₛ 2 corresponds to the actual stable state of the clock domain in response to the second input request IP 2. The second stable state signal C_{ss 2} may be activated when the state machine 104 enters an active mode (i.e., at time t₃₇) in response to the generation of the second input request IP 2.

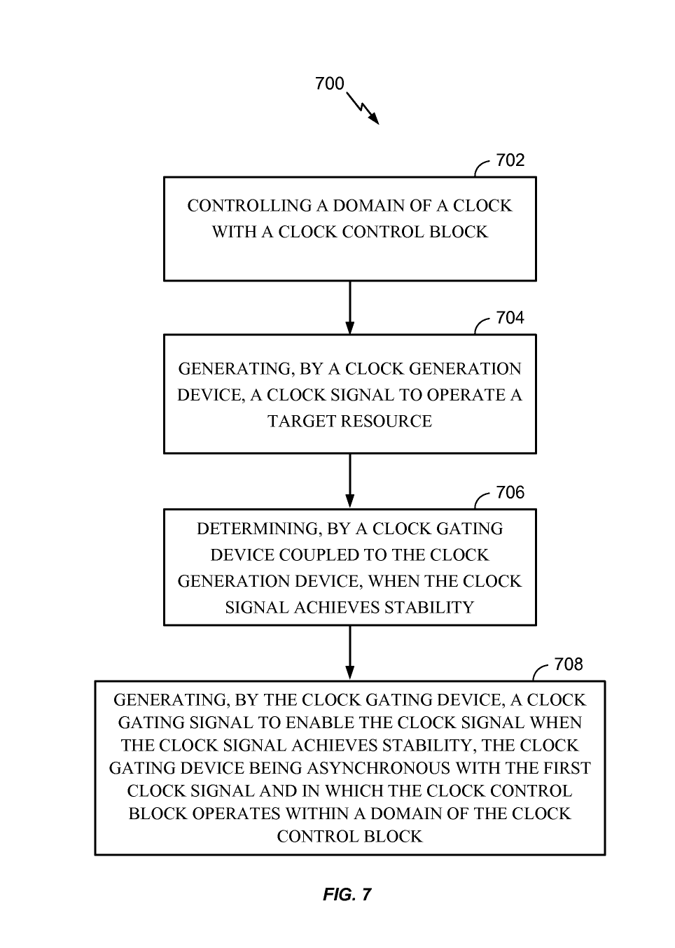

FIG. 7 illustrates an asynchronous clock enable method in accordance with one or more aspects of the disclosure.

In block 702, the asynchronous clock enable system controls a domain of a clock with a clock control block. In block 704, the system (e.g., a clock generating device of the system) generates a clock signal to operate a target resource. At block 706, the system (e.g., the clock gating device of the system) determines when the first clock signal achieves stability. At block 708, the system (e.g., the clock gating device) generates a clock gating signal to enable the clock signal when the clock signal achieves stability, the clock gating device being asynchronous with the first clock signal and in which the clock control block operates within a domain of the clock control block.

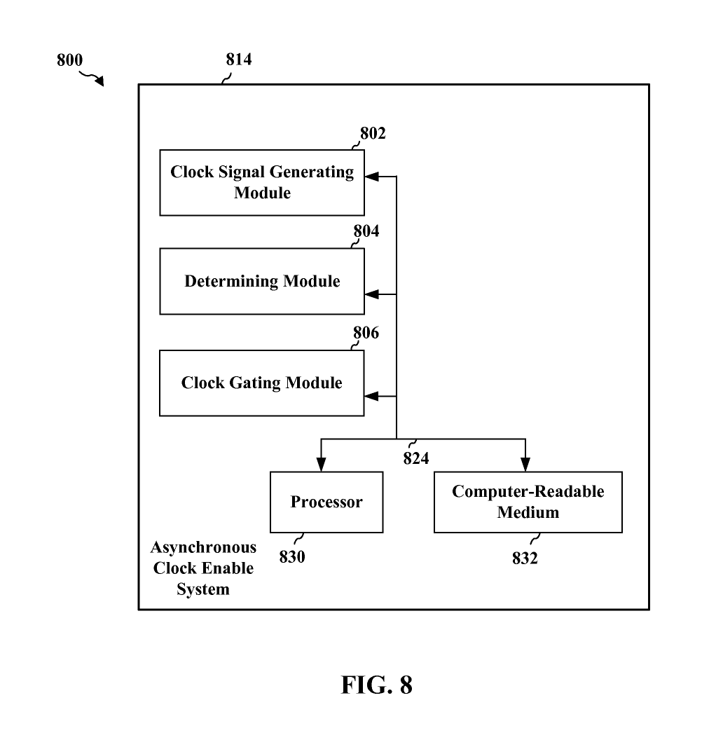

FIG. 8 is a diagram illustrating an example of a hardware implementation for an apparatus 800 employing an asynchronous clock enable system 814.

The apparatus 800 may include a clock signal generating module 802, a determining module 804 and a clock gating module 806. The asynchronous clock enable system 814 may be implemented with a bus architecture, represented generally by the bus 824. The bus 824 may include any number of interconnecting buses and bridges depending on the specific application of the asynchronous clock enable system 814 and the overall design constraints. The bus 824 links together various circuits including one or more processors and/or hardware modules, represented by the processor 830, the clock signal generating module 802, the determining module 804, the clock gating module 806, and the computer-readable medium 832. The bus 824 may also link various other circuits such as timing sources, peripherals, voltage regulators, and power management circuits, which are well known in the art, and therefore, will not be described any further.

The asynchronous clock enable system 814 includes the processor 830 coupled to a computer-readable medium 832. The processor 830 is responsible for general processing, including the execution of software stored on the computer-readable medium 832. The software, when executed by the processor 830, causes the asynchronous clock enable system 814 to perform the various functions described above for any particular apparatus. The computer-readable medium 832 may also be used for storing data that is manipulated by the processor 830 when executing software. The asynchronous clock enable system 814 further includes the clock signal generating module 802 for generating a first clock signal to operate a target resource. The asynchronous clock enable system 814 further includes the determining module 804 for determining when the first clock signal achieves stability. The asynchronous clock enable system 814 further includes the clock gating module 806 for generating a clock gating signal to enable the first clock signal when the first clock signal achieves stability. The modules may be software modules running in the processor 830, resident/stored in the computer readable medium 832, one or more hardware modules coupled to the processor 830, or some combination thereof.

In one configuration, the apparatus 800 includes means for generating a first clock signal. The aforementioned means may be one or more of the aforementioned elements of the radio access technology chip and/or the asynchronous clock enable system 814 of the apparatus 800 configured to perform the functions recited by the aforementioned means. As described above, the asynchronous clock enable system 814 may include the clock signal generating module 802. As such, in one configuration, the aforementioned means may be the clock signal generating module 802, the clock generation block 102, the asynchronous clock enable system 814 configured to perform the functions recited by the aforementioned means.

In one configuration, the apparatus 800 includes means for determining. The aforementioned means may be one or more of the aforementioned elements of the radio access technology chip and/or the asynchronous clock enable system 814 of the apparatus 800 configured to perform the functions recited by the aforementioned means. As described above, the asynchronous clock enable system 814 may include the determining module 804. As such, in one configuration, the aforementioned means may be the determining module 804, the state machine 104, the counter 106, the asynchronous clock enable system 814 configured to perform the functions recited by the aforementioned means.

In one configuration, the apparatus 800 includes means for generating a clock gating signal. The aforementioned means may be one or more of the aforementioned elements of the radio access technology chip and/or the asynchronous clock enable system 814 of the apparatus 800 configured to perform the functions recited by the aforementioned means. As described above, the asynchronous clock enable system 814 may include the clock gating module 806. As such, in one configuration, the aforementioned means may be the clock gating module 806, the state machine 104, the counter 106, the asynchronous clock enable system 814 configured to perform the functions recited by the aforementioned means.

### CONCLUSION AND ALTERNATE ASPECTS OF THE DISCLOSURE

Although specific circuitry has been set forth, it will be appreciated by those skilled in the art that not all of the disclosed circuitry is required to practice the disclosed embodiments. Moreover, certain well known circuits have not been described, to maintain focus on the disclosure.

The methodologies and systems described herein may be implemented by various means depending upon the application. For example, these methodologies may be implemented in hardware, firmware, software, or any combination thereof. For a hardware implementation, the processing units may be implemented within one or more application specific integrated circuits (ASICs), digital signal processors (DSPs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine or computer readable medium tangibly embodying instructions may be used in implementing the methodologies described herein. For example, software code may be stored in a memory and executed by a processor. When executed by the processor, the executing software code generates the operational environment that implements the various methodologies and functionalities of the different aspects of the teachings presented herein. Memory may be implemented within the processor or external to the processor. As used herein, the term “memory” refers to any type of long term, short term, volatile, nonvolatile, or other memory and is not to be limited to any particular type of memory or number of memories, or type of media upon which memory is stored.

Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium.

The machine or computer readable medium that stores the software code defining the methodologies and functions described herein includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer. As used herein, disk and/or disc includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The computer-readable medium may be embodied in a computer-program product. By way of example, a computer-program product may include a computer-readable medium in packaging materials. Those skilled in the art will recognize how best to implement the described functionality presented throughout this disclosure depending on the particular application and the overall design constraints imposed on the overall system.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

Although the present teachings and their advantages have been described in detail, it should be understood that various changes, substitutions and alterations can be made herein without departing from the technology of the teachings as defined by the appended claims. Moreover, the scope of the present application is not intended to be limited to the particular aspects of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding aspects described herein may be utilized according to the present teachings. Accordingly, the appended claims are intended to include within their scope such processes, machines, manufacture, compositions of matter, means, methods, or steps.

The description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, in which reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The foregoing description of one or more embodiments or aspects of the present disclosure has been presented for the purposes of illustration and description. It is not intended to be exhaustive or to limit the disclosure or the invention to the precise form disclosed. Many modifications and variations are possible in light of the above teaching. Although the present disclosure and invention has been described in connection with certain embodiments, it is to be understood that modifications and variations may be utilized without departing from the principles and scope of the disclosure or invention, as those skilled in the art will readily understand. Accordingly, such modifications would be practiced within the scope of the disclosure and invention, and within the scope of the following claims or within the full range of equivalents of the claims.

Further, the attached claims are presented merely as one aspect of the present invention. No disclaimer is intended, expressed, or implied for any claim scope of the present invention through the inclusion of this or any other claim language that is presented herein or may be presented in the future. Any disclaimers, expressed or implied, made during prosecution of the present application regarding the claims presented, changes made to the claims for clarification, or other changes made during prosecution, are hereby expressly disclaimed for at least the reason of recapturing any potential disclaimed claim scope affected by presentation of specific claim language during prosecution of this and any related applications. Applicant reserves the right to file broader claims, narrower claims, or claims of different scope or subject matter, in one or more continuation or divisional applications in accordance within the full breadth of the present disclosure, and the full range of doctrine of equivalents of the present disclosure, as recited in this specification.

What is claimed is:

1. An asynchronous clock enable system comprising:
a clock control block comprising:
a clock generation device; and
a clock gating device, coupled to the clock generation device, in which the clock control block operates within a domain of the clock control block.

2. The asynchronous clock enable system of claim 1, in which the clock control block further comprises a plurality of inputs, in which each input is independent of other inputs in controlling the clock gating device.

3. The asynchronous clock enable system of claim 2, in which a clock request is independent of the clock generation device.

4. The asynchronous clock enable system of claim 1, in which the clock gating device further comprises:
a state machine device coupled to the clock generation device;
a frequency stabilization counter coupled to the clock generation device via the state machine device, the frequency stabilization counter configured to count clock pulses of a clock signal, in which the clock gating device determines when the clock signal achieves stability based at least in part on a clock pulse count.

5. The asynchronous clock enable system of claim 4, in which the frequency stabilization counter and/or the state machine device identifies when the clock signal achieves stability based at least in part on a predetermined number of clock pulses and/or a worst-case settling time clock pulse count.

6. The asynchronous clock enable system of claim 1, further comprising a first logic device coupled to the clock generation device and the clock gating device, the first logic device configured to receive a clock signal and a clock gating signal and to output a stable clock signal when the clock signal achieves frequency stability.

7. The asynchronous clock enable system of claim 1, further comprising a first logic device coupled to the clock generation device, the first logic device configured to receive a first clock signal and an indication of when the first clock signal is glitchless and to output the glitchless first clock signal when it is indicated that the first clock signal is glitchless.

8. The asynchronous clock enable system of claim 7, in which the clock gating device determines when the glitchless first clock signal achieves frequency stability, the clock gating device configured to generate a clock gating signal to enable the glitchless first clock signal when the glitchless first clock signal achieves stability.

9. The asynchronous clock enable system of claim 8, in which the output of the glitchless and frequency stable clock signal is maintained when a delay between a first input request and a second input request is less than a clock smoothing period.

10. The asynchronous clock enable system of claim 8, in which the output of a glitchless and frequency stable clock signal is halted when a delay between a first input request and a second input request is shorter than a minimum threshold.

11. The asynchronous clock enable system of claim 1, in which a clock request is asynchronous with the clock control block domain.

12. The asynchronous clock enable system of claim 1, in which the clock gating device is independent of a clock pulse length and/or a clock logic level.

13. The asynchronous clock enable system of claim 12, in which the clock gating device achieves an active state based at least in part on one or more input requests.

14. The asynchronous clock enable system of claim 13, in which the clock generation device is active based at least in part on a clock control state machine.

15. The asynchronous clock enable system of claim 14, in which the clock generation device is active based at least in part on whether an input request is detected.

16. An asynchronous clock enable method comprising:
controlling a domain of a clock with a clock control block;
generating, by a clock generation device, a clock signal to operate a target resource;
determining, by a clock gating device coupled to the clock generation device, when the clock signal achieves stability; and
generating, by the clock gating device, a clock gating signal to enable the clock signal when the clock signal achieves stability, the clock gating device being asynchronous with the clock signal and in which the clock control block operates within a domain of the clock control block.

17. The asynchronous clock enable method of claim 16, further comprising: independently controlling the clock gating device with each of a plurality of inputs to the clock control block.

18. The asynchronous clock enable method of claim 17, further comprising: asynchronously requesting the clock signal from the clock generation device.

19. The asynchronous clock enable method of claim 16, further comprising:
coupling a state machine device and a frequency stabilization counter of the clock gating device to the clock generation device;
counting a clock pulse of the clock signal, by the frequency stabilization counter; and
determining, by the clock gating device, when the clock signal achieves stability based at least in part on a clock pulse count.
